(19) United States
(12) Patent Application Publication
(10) Pub. No.: US 2007/0155124 A1
(43) Pub. Date: Jul. 5, 2007

(54) Method of manufacturing semiconductor device

(75) Inventors: Jung Ryul Ahn, Seoul (KR); Jum Soo Kim, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/593,868

(22) Filed: Nov. 7, 2006

(30) Foreign Application Priority Data
Jan. 2, 2006 (KR) 2006-0000117

(51) Int. Cl. H01L 21/76

(52) U.S. Cl. 438/424

(57) ABSTRACT

A method of manufacturing a semiconductor device wherein a gate insulating layer and a polysilicon layer are formed over a semiconductor substrate in which a cell region and a peri region are defined. Portions of the polysilicon layer, the gate insulating layer, and the semiconductor substrate of the peri region are etched to form a first trench in the peri region. A first insulating layer is formed on the entire surface so that the first trench is gap filled. Portions of the first insulating layer, the first polysilicon layer, the gate insulating layer, and the semiconductor substrate of the cell region are etched to form second trenches in the cell region. A sidewall oxide layer and a nitride layer are formed within the second trenches, so that the sidewall oxide layer and the nitride layer are laminated. The second trenches are gap-filled with a second insulating layer to form isolation layers. Since plasma attack and the infiltration of hydrogen (H₂) can be prevented, the malfunction of a cell and peripheral circuits can be prevented.

### BACKGROUND

1. Field of the Invention

The invention relates generally to a method of manufacturing semiconductor devices and, more particularly, to a method of manufacturing semiconductor devices, wherein the malfunction of cells and peripheral circuits can be prevented by prohibiting plasma attack and the infiltration of hydrogen (H₂).

2. Discussion of Related Art

A general isolation layer formation process includes simultaneously forming trenches in the cell region and the peri region and gap-filling trenches with an oxide layer. As the trench width is narrowed due to the miniaturization of a device, however, it becomes difficult to gap fill the trench. To solve the problem, the following method is used.

First, the trench is gap filled using high energy plasma. Second, in order to improve the gap-fill ability, a HDP (high density plasma) oxide layer with a very high flow rate of H₂ is used. Third, SOG (spin on glass) with an excellent gap-fill ability is used. Fourth, a nitride layer is formed within the trench.

If the trench is gap filled using the above-described method, the following problems occur.

First, if plasma of high energy is used at the time of the trench gap-fill process, plasma attack is generated not only at the bottom area of the trench, but also on the sidewalls of the trench. Upon fabrication of a semiconductor device, an impurity ion, such as B, As, P or BF₂, is injected into the semiconductor substrate. If the above-described plasma attack is applied to the sidewalls of the trench, the ion concentration on the sidewalls of the trench abruptly decreases. Accordingly, the threshold voltage (Vt) drops to an undesirable low level, leading to the malfunction of the device.

Second, if the trench is gap filled using the HDP oxide layer, hydrogen (H₂) with a small atomic size is infiltrated into the interface of the gate insulating layer and the semiconductor substrate. It degrades the cycling characteristic and causes the failure of elements in the peri region.

Third, if the trench is gap filled using SOG with a good gap-fill characteristic, a degraded characteristic at the interface of the gate insulating layer and the semiconductor substrate, which is caused by plasma attack and the infiltration of hydrogen (H₂) due to high energy, can be prohibited, but a subsequent annealing process is required since SOG is not a solidified material.

To fabricate devices having a high level of integration, it is necessary that a gate insulating layer be formed on a channel having a narrow width (i.e., the active region) and a floating gate be formed on the gate insulating layer. However, if a subsequent annealing step is performed after the trench is gap filled with SOG, a polysilicon layer, which is generally used as the material of the semiconductor substrate and the floating gate, is oxidized, increasing the thickness of the gate insulating layer.

If the thickness of the gate insulating layer is increased as described above, the program and erase operation rates of the cell significantly decreases. Furthermore, since an oxide layer whose characteristic is difficult to predict not a pure gate insulating layer is added, it may cause failure in the read and write operations.

Fourth, if the nitride layer is deposited on the sidewalls of the trench, the diffusion of an injected impurity due to plasma attack can be prevented and the infiltration of hydrogen can be prohibited.

FIG. 1 is a graph illustrating variation in the threshold voltage Vt depending on a cycling number when the nitride layer is formed in the trench and when the nitride layer is not formed in the trench.

In the graph of FIG. 1, “a” denotes the threshold voltage Vt of a program cell when the nitride layer is not formed in the trench, “b” denotes the threshold voltage Vt of a program cell when the nitride layer is formed in the trench, “c” denotes the threshold voltage Vt of an erase cell when the nitride layer is not formed in the trench, and “d” denotes the threshold voltage Vt of an erase cell when the nitride layer is formed in the trench.

From FIG. 1, it can be seen that variation in the threshold voltage Vt is smaller in the graphs “b” and “d” in when the nitride layer is formed in the trench than in the graphs “a” and “c” in when the nitride layer is not formed in the trench. It shows that the graphs “b” and “d” in which variation in the threshold voltage Vt is small have a better cycling characteristic.

However, since the nitride layer has a very high electron trap concentration, a device may operate erroneously due to charges trapped at the nitride layer although a voltage is not applied to the gate in the case of a PMOS transistor.

### SUMMARY OF THE INVENTION

In one embodiment, the invention relates to a method of manufacturing a semiconductor device, wherein the malfunction in cells and peripheral circuits can be prevented by prohibiting plasma attack and the infiltration of hydrogen (H₂).

According to one aspect, the invention provides a method of manufacturing a semiconductor device, including the steps of forming a gate insulating layer and a polysilicon layer over a semiconductor substrate in which a cell region and a peri region are defined; etching the polysilicon layer, the gate insulating layer, and the semiconductor substrate of the peri region, thus forming a first trench in the peri region; forming a first insulating layer on the entire surface so that the first trench is gap filled, and etching portions of the first insulating layer, the first polysilicon layer, the gate insulating layer, and the semiconductor substrate of the cell region, thus forming second trenches in the cell region; forming a sidewall oxide layer and a nitride layer within the second trenches whereby the sidewall oxide layer and the nitride layer are laminated; and gap-filling the second trenches with a second insulating layer, thus forming isolation layers.

According to another aspect, the invention provides a method of manufacturing a semiconductor device, including the steps of forming a gate insulating layer and a polysilicon layer over a semiconductor substrate in which a cell region and a peri region are defined; etching the polysilicon layer, the gate insulating layer, and the semiconductor substrate to form a trench; forming an oxide layer and a nitride layer in the sidewalls of the trench; removing some or all of the nitride layer formed in the peri region; and forming an insulating layer to fill the trench.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a graph illustrating variation in the threshold voltage Vt depending on a cycling number when the nitride layer is formed in the trench and when the nitride layer is not formed in the trench;

FIGS. 2A to 2J are cross-sectional views illustrating a method of manufacturing a semiconductor device according to a first embodiment of the invention; and

FIGS. 3A to 3E are cross-sectional views illustrating a method of manufacturing a semiconductor device according to a second embodiment of the invention.

### DETAILED DESCRIPTION OF EMBODIMENTS

The invention will now be described in detail in connection with certain exemplary embodiments with reference to the accompanying drawings.

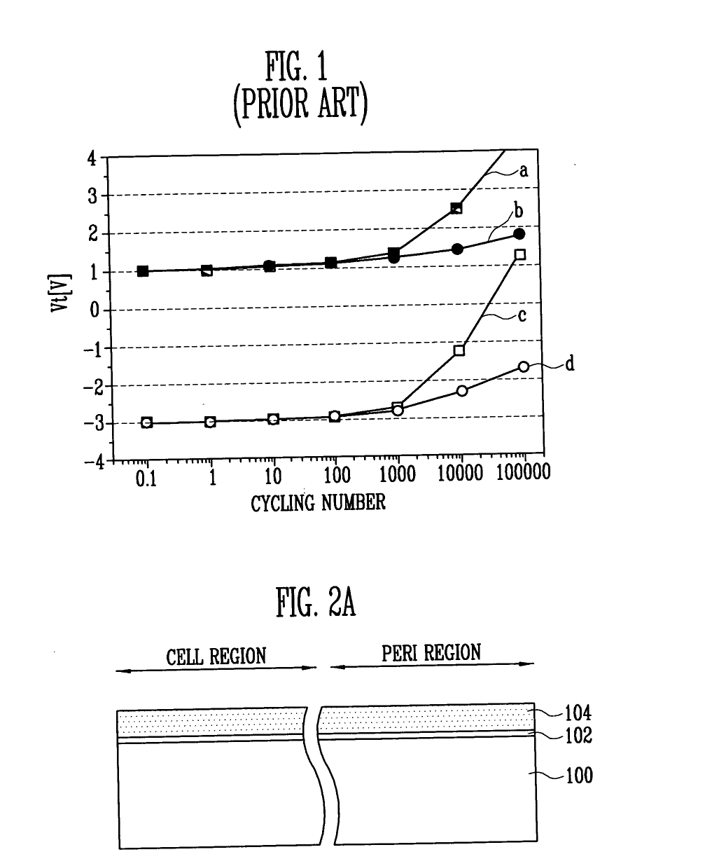

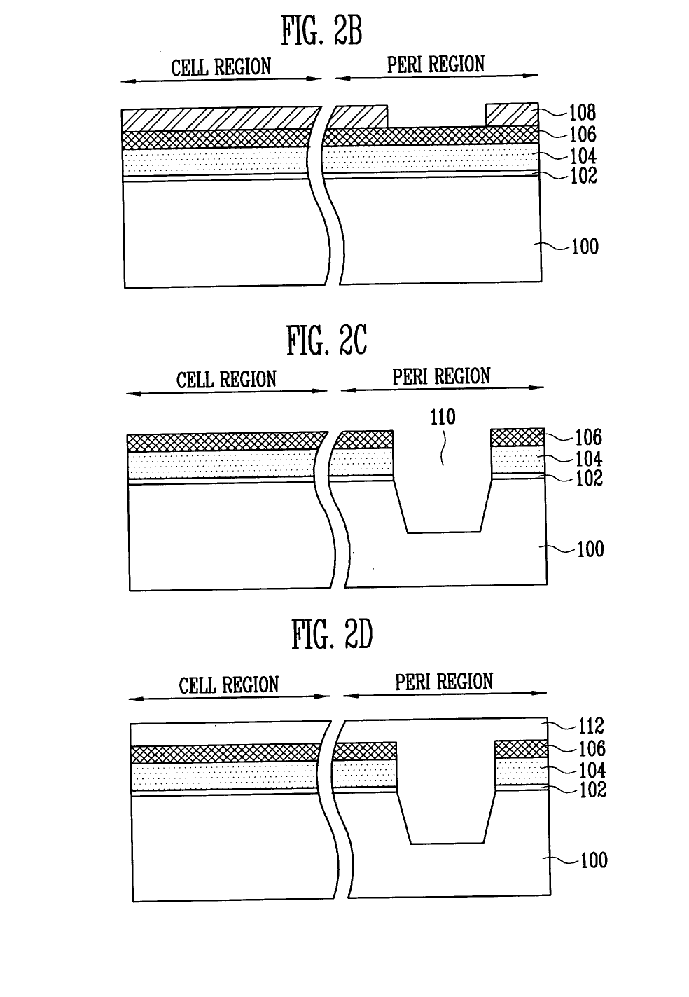

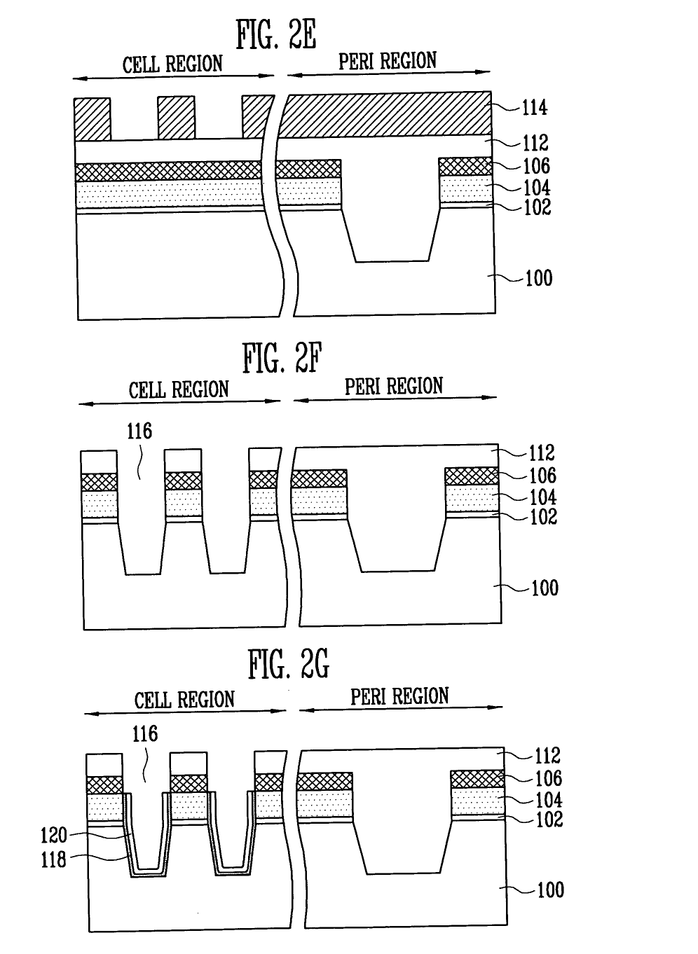

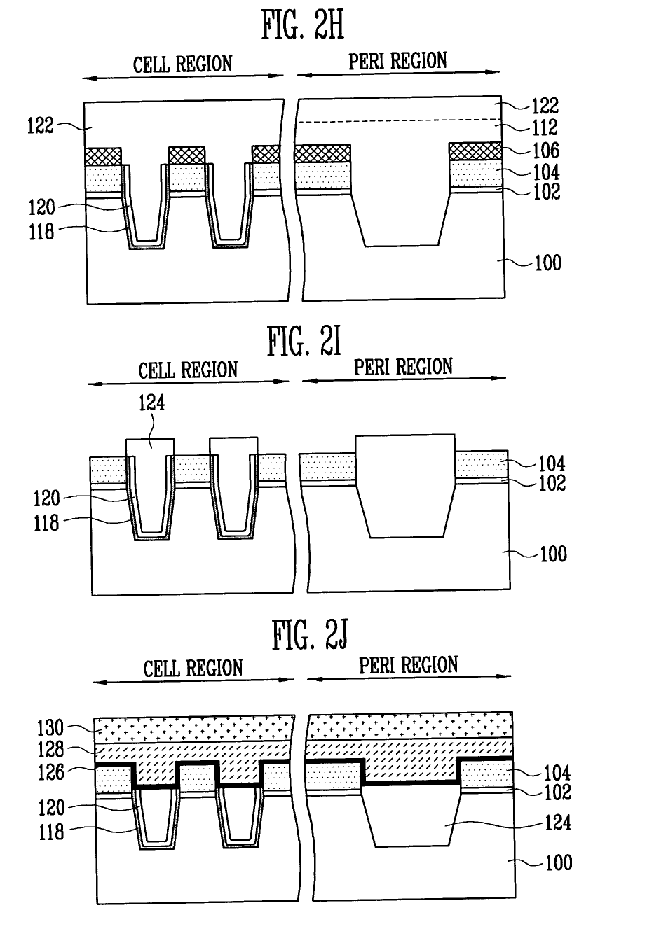

FIGS. 2A to 2J are cross-sectional views illustrating a method of manufacturing a semiconductor device according to a first embodiment of the invention.

Referring to FIG. 2A, an ion implantation process for forming a channel in a semiconductor substrate 100 in which a cell region and a peri region are defined is performed. A gate insulating layer 102 and a first polysilicon layer 104 for a floating gate are sequentially formed on the semiconductor substrate 100.

Referring to FIG. 2B, a hard mask layer 106 and a first photoresist are sequentially formed on the first polysilicon layer 104. The hard mask layer 106 may preferably be formed using a nitride layer. The first photoresist is etched using a photolithography process, forming a first photoresist pattern 108 through which a predetermined portion of the peri region is exposed.

Referring to FIG. 2C, after the hard mask layer 106 is etched using the first photoresist pattern 108 as an etch mask, the first photoresist pattern 108 is stripped. Portions of the first polysilicon layer 104, the gate insulating layer 102, and the semiconductor substrate 100 are etched using the patterned hard mask layer 106 as a mask, thus forming a first trench 110 in the peri region.

Referring to FIG. 2D, a first insulating layer 112 is formed on the entire surface in such a way to gap fill the first trench 110. The first insulating layer 112 may preferably be formed using SOG, Al₂O₃, TiO₂, TiN or nitride.

Referring to FIG. 2E, a second photoresist is formed on the entire surface. The second photoresist is etched by a photolithography process, thus forming a second photoresist pattern 114 through predetermined portions of the cell region are exposed.

Referring to FIG. 2F, after the first insulating layer 112 is etched using the second photoresist pattern 114 as an etch mask, the second photoresist pattern 114 is stripped. The patterned first insulating layer 112 serves as a hard mask. Portions of the hard mask layer 106, the first polysilicon layer 104, the gate insulating layer 102, and the semiconductor substrate 100 are etched using the patterned first insulating layer 112 as a mask, thus forming second trenches 116 in the cell region.

Referring to FIG. 2G, at the time of the etch process of the second trenches 116, the sidewalls of the second trenches 116 are attacked. In order to restore the attacked second trenches 116 and to prevent a direct junction of the semiconductor substrate 100 and a nitride layer 120 formed in a subsequent process, a sidewall oxide layer 118 is formed within the second trenches 116. Thereafter, in order to prevent plasma attack, the nitride layer 120 is formed within the second trenches 116, so that the sidewall oxide layer 118 and the nitride layer 120 are laminated. The nitride layer 120 may preferably be formed to a thickness of 10 Å to 300 Å.

Referring to FIG. 2H, a second insulating layer 122 is formed on the entire surface so that the second trenches 116 are gap filled. The second insulating layer 122 may preferably be formed using SOG, Al₂O₃, TiO₂, TiN or nitride.

Referring to FIG. 2I, the second insulating layer 122 and the first insulating layer 112 are polished until a top surface of the hard mask layer 106 is exposed, forming isolation layers 124. The hard mask layer 106 is then stripped. The hard mask layer 106 may be stripped by a wet or dry etch process.

Referring to FIG. 2J, in order to lower the EFH (effective field height) of the isolation layers 124, top surfaces of the isolation layers 124 are etched. At this time, the surfaces of the isolation layers 124 are lower in height than a surface of the first polysilicon layer 104.

A dielectric layer 126, a second polysilicon layer 128 for a control gate, and a tungsten layer 130 are sequentially formed on the entire surface.

As described above, since the nitride layer 120 formed within the second trenches 116 serves as a barrier, the concentration of injected ions is not decreased and the infiltration of hydrogen (H₂) atoms into the interface of the gate insulating layer 102 and the semiconductor substrate 100 can be prevented.

Furthermore, since the nitride layer 120 serves as a barrier, the polysilicon layer used as the material of the semiconductor substrate 100 and the floating gate can be prevented from being oxidized although an annealing process is performed after the second trenches 116 is gap filled with SOG. It is therefore possible to maintain the thickness and tunneling characteristic of the gate insulating layer 102 without change.

In addition, since the nitride layer 120 is formed only in the cell region, a charge trap problem occurring only in the PMOS transistor of the peripheral circuits can be solved and the malfunction of the PMOS transistor can be prevented accordingly.

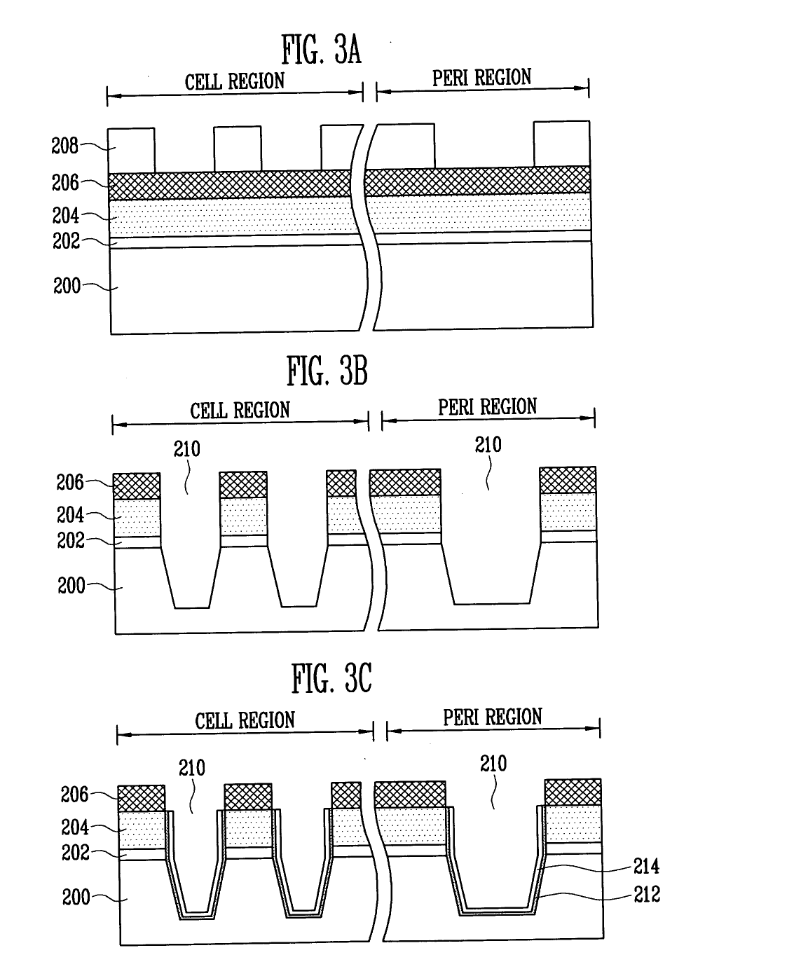

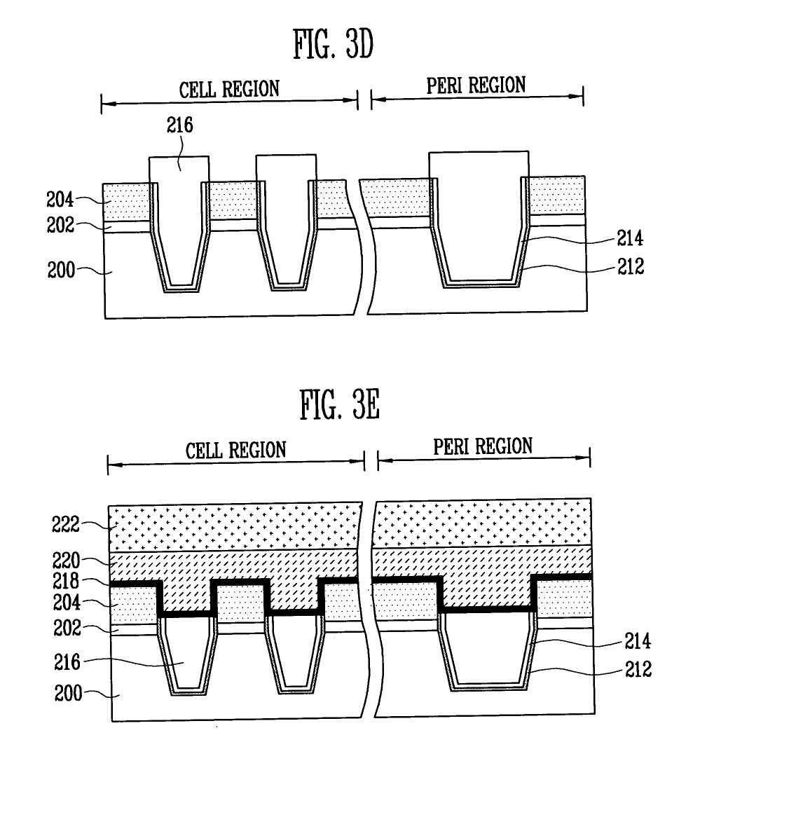

FIGS. 3A to 3E are cross-sectional views illustrating a method of manufacturing a semiconductor device according to a second embodiment of the invention.

Referring to FIG. 3A, an ion implantation process for forming a channel in a semiconductor substrate 200 in which a cell region and a peri region are defined is performed. A gate insulating layer 202, a first polysilicon layer 204 for a floating gate, a hard mask layer 206, and a photoresist are sequentially formed on the semiconductor substrate 200. The hard mask layer 206 may be formed using a nitride layer. The photoresist is etched by a photolithography process, thus forming a photoresist pattern 208 through which predetermined portions of the cell region and the peri region are exposed.

Referring to FIG. 3B, after the hard mask layer 206 is etched using the photoresist pattern 208 as an etch mask, the photoresist pattern 208 is stripped. Portions of the first polysilicon layer 204, the gate insulating layer 202, and the semiconductor substrate 200 are etched using the patterned hard mask layer 206 as a mask, forming trenches 210.

Referring to FIG. 3C, the sidewalls of the trenches 210 are attacked during the process of etching the trenches 210. In order to restore the attacked trenches 210 and to prevent the semiconductor substrate 200 and a nitride layer 214 formed in a subsequent process from being directly combined, a sidewall oxide layer 212 is formed within the second trenches 210.

Thereafter, in order to prevent plasma attack, the nitride layer 214 is formed within the trenches 210, so that the sidewall oxide layer 212 and the nitride layer 214 are laminated. The nitride layer 214 may preferably be formed to a thickness of 10 Å to 300 Å. At this time, a thickness of the nitride layer 214 formed in the cell region is preferably thicker than that of the nitride layer 214 formed in the peri region.

Though not shown in the drawings, the nitride layer 214, which is formed in some transistor regions of the peripheral circuits (that is, a NMOS transistor region and a portion of a PMOS transistor region in which a device operates even when a voltage is not applied to the gate due to charges trapped at the nitride layer 214), is then removed. The nitride layer 214 may be removed by a wet or dry etch process.

The nitride layer 214 is formed within the trenches 210 of some transistor regions (a portion of the PMOS transistor region of the peripheral circuits) as described above so that the nitride layer 214 can prevent boron (B) within the polysilicon layer 104 from escaping to the outside due to a subsequent annealing process.

Referring to FIG. 3D, an insulating layer is formed on the entire surface so that the trenches 210 are buried. The insulating layer may preferably be formed using Al₂O₃, TiO₂, TiN, or nitride. The insulating layer is polished until a top surface of the hard mask layer 206 is exposed, thereby forming isolation layers 216. The hard mask layer 206 is then stripped. The hard mask layer 206 may be stripped by a wet or dry etch process.

Referring to FIG. 3E, in order to lower the EFH of the isolation layers 216, top surfaces of the isolation layers 216 are etched. At this time, the surfaces of the isolation layers 216 are lower in height than a surface of the first polysilicon layer 204. A dielectric layer 218, a second polysilicon layer 220 for a control gate, and a tungsten layer 222 are sequentially formed on the entire surface.

The invention as described above is applied to a flash memory device. However, the invention may be applied to all devices including the PMOS transistor of the peripheral circuit and the cell region, thereby preventing the malfunction of the device.

Furthermore, in the case of a DRAM, a cell is formed of a NMOS transistor with a high level of integration and peripheral circuits for driving the cell are used both in the NMOS transistor and the PMOS transistor. Therefore, effective trenches can be formed using the invention.

As described above, the invention may have at least the following advantages.

First, since the nitride layer formed in the trench of the cell region serves as a barrier, the concentration of injected ions is not decreased and plasma attack can be prevented.

Second, the nitride layer can prevent the infiltration of hydrogen (H₂) atoms into the interface of the gate insulating layer and the semiconductor substrate 100.

Third, since the nitride layer serves as a barrier, the polysilicon layer used as the material of the semiconductor substrate and the floating gate can be prevented from being oxidized although annealing is implemented after the second trenches are gap filled with SOG. It is therefore possible to maintain a thickness and tunneling characteristic of the gate insulating layer without change.

Fourth, since the nitride layer is formed only in the cell region, the malfunction of the PMOS transistor of the peri region can be prevented.

Fifth, trenches of the cell region having a high level of integration can be gap filled easily using an existing gap-fill apparatus without additional equipment.

While the invention has been described in connection with practical exemplary embodiments, the invention is not limited to the disclosed embodiments but, to the contrary, is intended to cover various modifications and equivalent arrangements included within the spirit and scope of the appended claims.

What is claimed is:

1. A method of manufacturing a semiconductor device, the method comprising the steps of:
forming a gate insulating layer and a polysilicon layer over a semiconductor substrate in which a cell region and a peri region are defined;
etching the polysilicon layer, the gate insulating layer, and the semiconductor substrate of the peri region to form a first trench in the peri region;
forming a first insulating layer to fill the first trench;
etching the first insulating layer, the first polysilicon layer, the gate insulating layer, and the semiconductor substrate of the cell region to form a second trench in the cell region;
forming an insulating spacer in the sidewalls of the second trench; and
forming a second insulating layer to fill the second trench.

2. The method of claim 1, comprising forming at least one of the first insulating layer and the second insulating layer is formed using SOG, Al₂O₃, TiO₂, TiN, or nitride.

3. The method of claim 1, wherein the insulating spacer is formed an oxide layer and a nitride layer

4. The method of claim 3, comprising forming the nitride layer to a thickness of 10 Å to 300 Å.

5. The method of claim 1, comprising after the isolation layers are formed, further etching top surfaces of the isolation layers.

6. The method of claim 5, wherein the surfaces of the isolation layers, which have been further etched, are lower in height than a surface of the polysilicon layer.

7. A method of manufacturing a semiconductor device, the method comprising the steps of:
forming a gate insulating layer and a polysilicon layer over a semiconductor substrate in which a cell region and a peri region are defined;
etching the polysilicon layer, the gate insulating layer, and the semiconductor substrate to form a trench;
forming an oxide layer and a nitride layer in the sidewalls of the trench;
removing some or all of the nitride layer formed in the peri region; and
forming an insulating layer to fill the trench.

8. The method of claim 7, comprising forming the insulating layer using SOG, Al₂O₃, TiO₂, TiN, or nitride.

9. The method of claim 7, comprising forming the nitride layer to a thickness of 10 Å to 300 Å.

10. The method of claim 7, wherein a thickness of the nitride layer formed in the cell region is thicker than a thickness of the nitride layer in the peri region.

11. The method of claim 7, comprising removing the nitride layer by a wet process or a dry etch process.

12. The method of claim 7, comprising after the isolation layers are formed, further etching top surfaces of the isolation layers.

13. The method of claim 12, wherein the surfaces of the isolation layers, which have been further etched, are lower in height than a surface of the polysilicon layer.
